(19) United States
(12) Patent Application Publication
(10) Pub. No.: US 2013/0220694 A1
(43) Pub. Date: Aug. 29, 2013

(54) Thin Pocket Liner and Pad for Protection Against Electromagnetic Exposure when Carrying and/or Using Electronic Devices

(71) Applicants: Susan Kay Wittman-Holloway, Boulder, CO (US); Christopher L. Holloway, Boulder, CO (US)

(72) Inventors: Susan Kay Wittman-Holloway, Boulder, CO (US); Christopher L. Holloway, Boulder, CO (US)

(21) Appl. No.: 13/775,778

(22) Filed: Feb. 25, 2013

Related U.S. Application Data
(60) Provisional application No. 61/634,254, filed on Feb. 27, 2012.
(60) Provisional application No. 61/634,255, filed on Feb. 27, 2012.

(51) Int. Cl. H05K 9/00

(52) U.S. Cl. CPC H05K 9/0043
USPC 174/378

(57) ABSTRACT

This patent application is associated with the provisional patent applications No. 61/634,254 and No. 61/634,255 which claims the filing date of Feb. 27, 2012. This patent application is for a device which can be described as a pocket liner (and pad) designed to protect individuals from close contact to electromagnetic exposure when they carry (or using) their electronic devices close to their bodies. Studies have shown that exposure to excess electromagnetic radiation has harmful effects to humans. This device is designed to protect the user from those effects by significantly reducing exposure to electromagnetic energy from personal electromagnetic devices with minimal interference to the normal operation of the electronic device. In some realizations, the device is designed to also protect users from thermal exposure.

This patent application is associated with the provisional patent applications No. 61/634,254 and No. 61/634,255 which claims the filing date of Feb. 27, 2012.

### BACKGROUND OF THE INVENTION

This patent application is for a device which is conceived as a pocket liner (and/or pad) designed to protect individuals from close contact to electromagnetic exposure when they carry (or using) their electronic devices close to their bodies such as in the pockets of their clothing. Studies have shown that exposure to excess electromagnetic radiation has harmful effects, especially when users carry their electronic devises close to the skin of the body. Users of electronic devices such as smart-phones and compact interactive devices commonly carry their electronic devices in the pockets of their clothing. In fact, these devices are intentionally designed to fit into the pockets of clothes.

When personal electronic devices are carried in this way (in the pockets of clothing, and therefore very close to the body), there is little to no protection against potentially harmful electromagnetic radiation. However, the intent and purpose of carrying the device in the pocket is constant readiness for contact and response via electromagnetic signals to outside sources. The electronic device, therefore, is constantly emitting electromagnetic and/or thermal energy. The thermal energy is due to the power source i.e., the battery, and the electromagnetic radiation is used to enable receipt of incoming signals. The relative time that electronic devices are in this inactive but “alert” state far exceeds the time for active use of most devices in all but the most precocious of pocket sized electromagnetic device users.

Therefore, this patent provides a design of a pocket liner (and pad) that both protects against electromagnetic and/or thermal radiation while allowing the device to function. That is, the device may receive information via electromagnetic signals such as text messages or phone calls, yet the person carrying the electronic device experiences reduced impact from the radiative energy of the signal. This design varies from past designs in a number of ways; 1) it allows the electronic device to remain in a state of functional constant alertness, 2) it allows the user to carry the device close to the body in a manner that is familiar and ready to use, as the device was designed to be used, and 3) it allows unimpeded access to the phone that requires no extra movement or behaviors for access.

The device can be manufactured as a pad or mat. In this realization the device (i.e., protective pad) is placed on the lap and under a laptop computer (or large electronic device) in order to protect the user from both thermal and electromagnetic energy.

Various methods exist for protection against the harmful effects of electronic energy that is produced by personal electronic devices held close to the body. The prior art utilizes different approaches to achieve the benefits claimed herein. Past applications for electromagnetic protective devices rely on distancing the device from the body such as US patent number US 20130029725 A1 which proposed a “wireless” phone with a 10″ wire so that the phone must be held a sufficient distance from the body during conversation. The present art is focused on protection in the passive receptor state of the electronic device which accounts for the lion's share of the time in close physical contact with the device. Further, the present device includes neither extraordinary movements by the user nor extra, confounding equipment that is attached to the electronic device.

Another approach has been to distance an electronic device away from vital organs of the body. For example, US patents number US 20120217275 A1 proposes to carry electromagnetic devices on the wrist. While a devise carried on the wrist or other remote body part may reduce exposure to sensitive genitalia (as in the case for a device carried in the pants pockets), or the heart (as in the case for shirt pocket storage), a wrist device requires the user to take extraordinary care to avoid damage. Also, the device are may require extra movement (such as unbuckling or buttoning) in order to access the device.

Another approach in past art has included the notion of sequestering personal electromagnetic devices in a closed pouch that mitigates electromagnetic energy. This approach is illustrated in US 2012/0114270 A1. This example of prior art (US 2012/0114270 A1) encloses the entire electronic device and hence, the normal operating procedure of the electronic device is not possible unless one attaches additional antennas or devices to the original electronic device. The design in the present patent application varies from this type of past art in that 1) once placed in the pocket, the electronic device operates in its intended fashion without having to attach additional equipment such as antennas or extending wires or cables, and 2) the present design only shields energy on the body side of the device so that it allows the electronic device to receive signals while still in the pocket as it is designed to do, and 3) the newly designed protective pocket does not require added movement by the user such as unlocking, undoing, or any extra retrieval movement of the electronic device. This means that the electronic device continues to act in a functional way, yet minimizes exposure to harmful electromagnetic radiation.

Yet another shielding approach uses magnets to block the impact of electromagnetic energy (US 20120247827 A1). However, the user must wear special spectacles with attached interfering magnets on the ear stem in order to execute the operational mode of this design. Also, this design focuses on the active use of the cell phone which often accounts for a small fraction of the electromagnetically active time portion when considering the use of personal electromagnetic devises. That is, the only protective time is when the device is in use.

The material of this pocket liner (and pad) can also be designed to incorporate electromagnetic protection, or thermal protection, or both electromagnetic and thermal protection. That is, the device can reduce the impact of harmful thermal heating of the body due to the electronic device as well as to reduce the harmful effects of electromagnetic energy.

### SUMMARY OF THE INVENTION

Electromagnetic devices are often carried in pockets that are close to the human body, and even close to vital organs. As a result, people are exposed to long term electromagnetic emissions at close range. This pocket liner is this invention significantly reduces human exposure to long term electromagnetic energy which has been shown to be harmful in some environments. The pocket liner is flexible and can be folded or sewn into shapes that create pockets within which can be placed an electronic device. The pocket liner is essentially a pouch made from two different type of material. One side of the pocket liner (the side that is closest to the body) is made from an electromagnetic shielding material (and if desired could have thermal shielding properties) and the other side of the pocket liner is made of non-shielding materials. The material from which the pocket liner device is made is flexible electromagnetic shielding material as such the pocket liner can be a stand-alone pouch or can be affixed (or sewn) to the pocket of the user's clothing. For the stand alone pocket liner, the electromagnetic device can be placed in the pocket liner and then placed in the pocket of the user's clothing.

This device in this patent application is a pocket liner that is designed to protect individuals from close contact electromagnetic exposure when they carry their electronic devices in their clothing and therefore, close to their bodies. The device is made from a flexible, cloth-like material that may a stand-alone pouch or can be sewn or otherwise affixed to the body side surface of a clothing pocket. As the electronic device is carried by the user, the pocket liner is situated between the user's skin and the electronic device thereby significantly reducing exposure to electromagnetic energy. The pocket liner is designed such that the electrical device is not completely enclosed by a shielding material; allowing it to function in its intended manner, see FIG. 1 and FIG. 2. The shape and designs of the pocket device protects a user from electromagnetic energy (via the shielding material on the body side of the pocket, see FIGS. 1 and 2), but it still allows for the electronic device to operate in its intended manner.

The pocket shield does not impede the ready access or use of the electronic device, but acts as a flexible but functional barrier between the user and the electronic device. The user need not interact with the pocket shield, and there is no extra opening or closing or other manipulating action that is required for the shield to function once it is in place in the user's clothing. In fact, the user should be unaware of the existence of the pocket shield during its use.

One example of this shielding pocket is shown in FIGS. 1 and 2 on the attached figure sheet. The pocket liner is flexible and cloth like. It is not rigid, but can conform to the shape of whatever pocket is used to carry electronic devices. The pocket liner may be permanently affixed to the clothing or may be transferable from pocket to pocket like a pocket protector for pens, see FIG. 3. One final application of the pocket liner is with the use of laptop computer (or large electronic device), in which the device is a liner and/or protection pad, see FIG. 4. The device can be manufactured as a pad or mat. In this realization the device (i.e., protective pad) is placed on the lap and under a laptop computer (or large electronic device) in order to protect the user from both thermal and electromagnetic energy.

### BRIEF DESCRIPTION OF THE DRAWINGS

FIG. 1 illustrates the pocket liner for electronic device, front view. The pocket liner in this figure is an illustration of one example pocket liner in which the material that is intended to be used closest to the body is made of a shielding material. The side away from the body is made of a non-shielding material.

FIG. 2 illustrates the pocket liner for electronic device, side view. The pocket liner in this figure is an illustration of one example pocket liner in which the material that is intended to be used closest to the body is made of a shielding material. The side away from the body is made of a non-shielding material.

FIG. 3 illustrates how the pocket liner can be inserted into the pocket of clothing. This pocket liner can also be sewed into pockets of existing pockets.

FIG. 4 illustrates how the pocket liner can also be used as a pad for a laptop when placed on the lap, and as such protects the body from both electromagnetic and thermal exposure.

FIG. 5 illustrates a layered (and combined) thermal and electromagnetic shielding material. The device can be constructed as either a layered thermal and electromagnetic shielding materials or be constructed with a combination of thermal and electromagnetic shielding materials (in which the electromagnetic shielding material is imbedded into the thermal material).

### DETAILED DESCRIPTION OF THE INVENTION

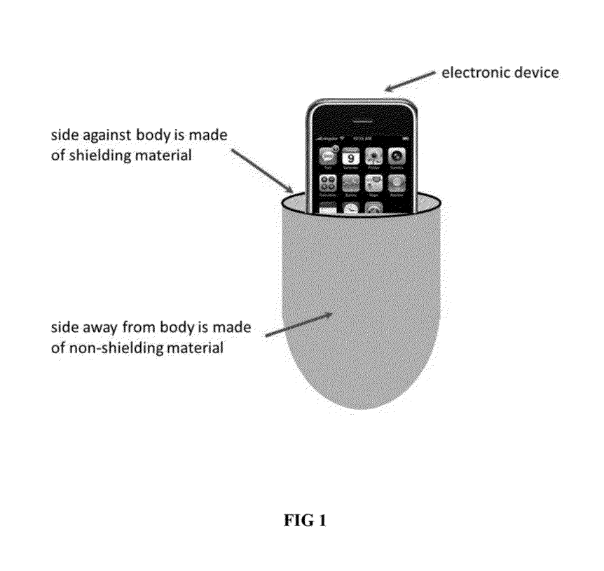

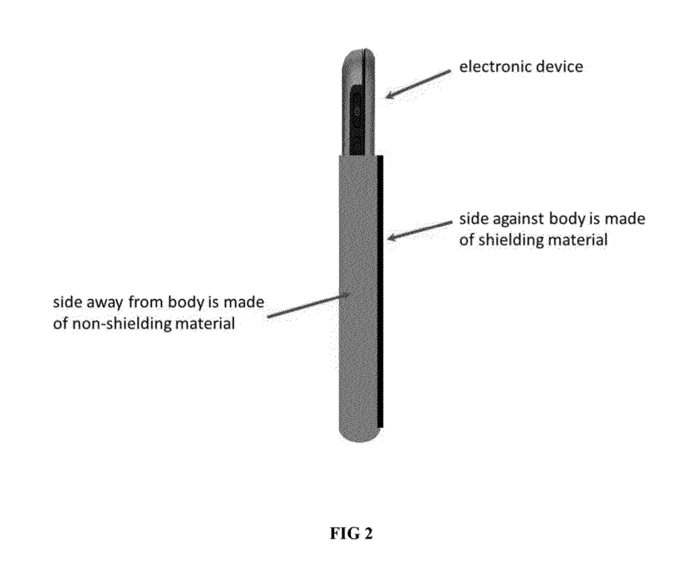

This device in this patent is a pocket liner that is designed to protect individuals from close contact electromagnetic exposure when they carry their electronic devices in their clothing and close to their bodies. The device can also be realized as a protection pad for use with laptop computers (or large electronic devices). The device is made from a flexible material that may be sewn or otherwise affixed to the body side surface of a clothing pocket or it can be a stand-alone pouch (like a pocket liner for pens). As the electronic device is carried by the user, the pocket liner is situated between the user's skin and the electronic device thereby significantly reducing exposure to electromagnetic energy. The liner is designed such that the electrical device is not completely enclosed by a shielding material; allowing it to function in its intended manner, see FIG. 1 and FIG. 2. The shape and designs of the pocket device protect a user from electromagnetic energy (via the shielding material on the body side of the pocket, see FIG. 1 and FIG. 2), but it still allows for the electronic device to operate in its intended manner.

The pocket shield does not impede the ready access or use of the electronic device, but acts as a flexible but functional barrier between the user and the electronic device. The user need not interact with the pocket shield, and there is no extra opening or closing or other manipulating action that is required for the shield to function once it is in place in the user's clothing. In fact, the user should be unaware of the existence of the pocket shield during its use.

The device is flexible and can be folded or sewn into shapes that create pockets within which can be placed an electronic device. The material from which the device is made is flexible electromagnetic shielding material that can be affixed to the material of a user's pocket. Electromagnetic devices are often carried in pockets that are close to the human body, and even close to vital organs. As a result, people are exposed to long term electromagnetic emissions at close range. This pocket liner significantly reduces human exposure to long term electromagnetic energy which has been shown to be harmful in some environments.

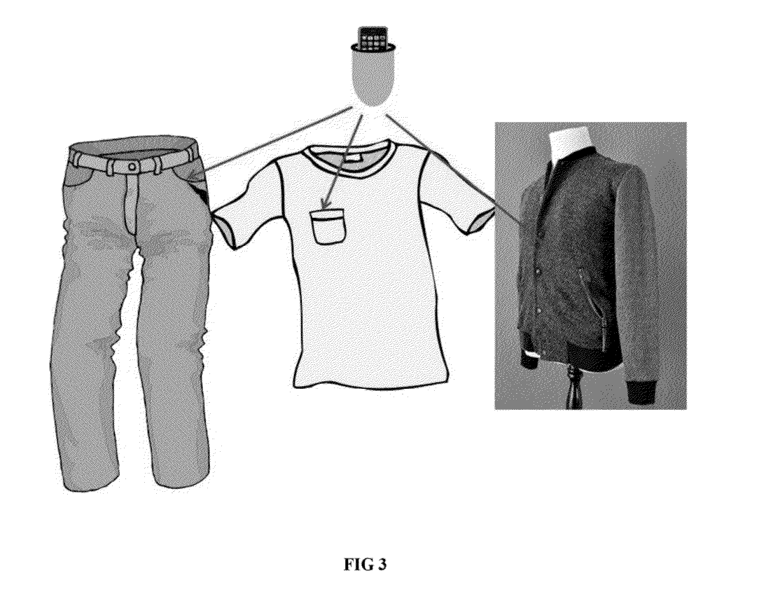

One example of this is the shielding pocket shown in FIG. 1 and FIG. 2 on the attached figure sheet. The pocket liner is flexible and cloth like. It is not rigid, but can conform to the shape of whatever pocket is used to carry electronic devices. The pocket liner may be permanently affixed to the clothing or may be transferable from pocket to pocket like a pocket protector for pens, see FIG. 3. This pocket liner can also be sewn into existing cloth pockets.

The shielding pocket liner can also be manufactured in a manner that is form fitting to the electronic device, much like a cover to a cell phone. In this configuration, the material of the cover that is closest to the body is made from an electromagnetic shielding material (and if desired could have thermal shielding properties as well), while the other sides of the cover are non-shielding, hence allowing the electronic device to operate in its intended manner.

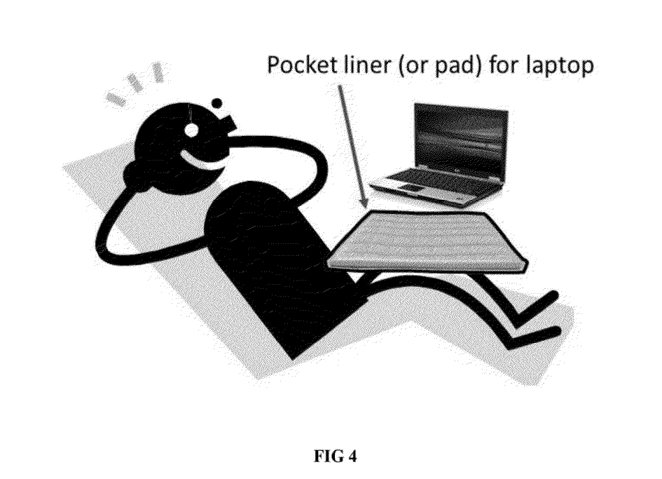

One final application of the pocket liner is with the use of laptop computers, see FIG. 4. In this configuration the pocket liner is used as a pad for a laptop when placed on lap of the user, and as such protects the body from both electromagnetic and thermal exposure. The electromagnetic and thermal shielding properties of the pocket liner will aid in reducing the potential harmful exposure in the human body. It this realization, the device could be designed as a layer of different materials (for both electromagnetic and thermal shielding), without the need for a pouch design. That is, the laptop would not be placed in a liner or pouch, but the laptop computer would be placed on the top of the device to serve as a pad (or buffer layer) between the laptop computer and the body, see FIG. 4.

The device can be manufactured as a pad or mat. In this realization the device (i.e., protective pad) is placed on the lap and under a laptop computer (or large electronic device) in order to protect the user from both thermal and electromagnetic energy.

Besides utilizing this device as a simple, flat pad, the device can be constructed into a soft, flexible carrying case for laptop computers. When a computer or large electronic device is being used, it can be removed from the shielding device so that the soft case can be placed upon the lap and act as a shield for the person using it.

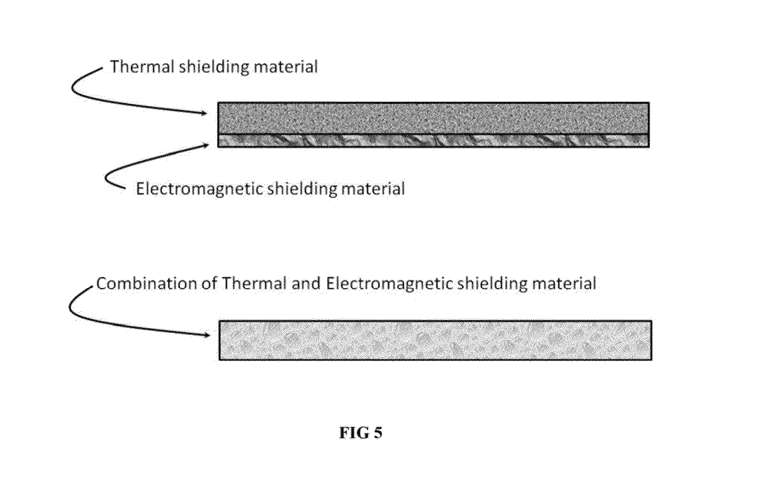

The device can be constructed as either a layered thermal and electromagnetic shielding materials or be constructed with a combination of thermal and electromagnetic shielding materials (in which the electromagnetic shielding material is imbedded into the thermal material), see FIG. 5.

What is claimed is:

1. A portable pocket liner or pouch for an electronic device that is made of material that provides electromagnetic shielding on the body side, but also allows the device to work properly by allowing radiation to occur away from the body.

2. The invention of claim 1, wherein the protective pouch is sown into or fitted into clothing and acts as a pocket.

3. The invention of claim 1, wherein the pocket of clothing is made of protective material as it is manufactured.

4. The inventions of claims 1-3, in which the protective material is designed to protect against thermal exposure.

5. The inventions of claims 1-4, in which a larger sized pocket is designed for laptop style computers such that the computer can be placed on the pocket while in use on your lap (to serve as both an electromagnetic and thermal protection pad for the user's lap), or while being carried in a backpack or briefcase for the intended protection.

6. The inventions of claim 1-5, in which the device would be designed as a layer of different materials (for both electromagnetic and the thermal shielding), without the need for a pouch design. That is, the laptop would no be placed in a liner or pouch, but the laptop computer would be placed on the top of the device to serve as a pad (or buffer layer) between the laptop computer (or large electronic device) and the body.

7. The inventions of claim 1-6, in which the dives is manufactured as a pad or mat. This claim covers a device to be placed on the lap and under a laptop computer (or large electronic device) in order to protect the user from both thermal and electromagnetic energy.

8. The inventions of claim 1-7, in which the pocket liner is made from a material that is form-fitted (like a rigid cover) to the electric device.
